(19) United States
(12) Patent Application Publication
(10) Pub. No.: US 2011/0309414 A1
(43) Pub. Date: Dec. 22, 2011

(54) Diode polarity for diode array

(76) Inventor: Daniel Robert Shepard, North Hampton, NH (US)

(21) Appl. No.: 12/930,655

(22) Filed: Jan. 13, 2011

Related U.S. Application Data
(60) Provisional application No. 61/355,907, filed on Jun. 17, 2010.

(51) Int. Cl. H01L 27/08; H01L 21/82

(52) U.S. Cl. 257/208; 438/128; 257/E27.046; 257/E21.602

(57) ABSTRACT

A memory-array is disclosed in which an array of non-linear conductors such as diodes is constructed having an area per memory cell of 4F² and comprises a plurality of conductors fabricated as doped semiconductor conducting lines in the substrate such that, during normal operation, an unselected conductor has a zero bias to the substrate and a selected conductor has a reverse bias to the substrate for minimizing current leakage

### CROSS-REFERENCE TO RELATED APPLICATION

This application claims priority to and the benefit of, and incorporates herein by reference in its entirety, U.S. Provisional Patent Application No. 61/355,907 by Shepard titled “DIODE POLARITY FOR DIODE ARRAY” which was filed on Jan. 13, 2010. This application makes reference to and incorporates herein by reference in its entirety, U.S. Pat. No. 5,673,218, by Shepard titled “Dual-Addressed Rectifier Storage Device” that issued on Sep. 30, 1997.

### TECHNICAL FIELD

In various embodiments, the present invention relates to diode arrays as they relate to memory devices, and more particularly to the diode direction with respect to the substrate surface (i.e., direction of current flow with respect to the resulting diodes) for diodes having a conductive element formed in the substrate as doped semiconductor.

### BACKGROUND

As advances continue to be made in the area of semiconductor memory devices, high capacity and low cost will be increasingly important. In particular, memory cell designs having a footprint no larger than 4F² are increasingly desired to provide high density. For this reason, much is being done in the current art utilizing diode arrays for memory designs.

In a diode array storage device (for example, as described in U.S. Pat. No. 5,673,218, by Shepard titled “Dual-Addressed Rectifier Storage Device”), a memory cell is present at the intersection of a row and a column. If the rows and the columns as well as the spaces therebetween are all sized at the critical dimension (F), then a memory cell will have an area of 4F². A bit is addressed by selecting one row through the array and one column through the array whereby said selected row and column intersect at a targeted storage location. If the rows are the array dimension to which the storage diode anodes are connected and the columns are the other array dimension to which the storage diode cathodes are connected, selection of a row is accomplished by applying a high voltage and selection of a column is accomplished by selecting a low voltage such that the diode at the point of intersection of the selected row and the selected column is forward biased. The non-selected rows and columns would have a voltage present such that a diode at the intersection of a non-selected row and a non-selected column would see a zero, a reverse, or a very small forward bias; the source of the non-selected rows and columns typically is high impedance or floating so as not to induce or enable significant leakage currents. The binary state of the addressed bit is determined by the resulting current path—if a low impedance current path is present it represents one logic state and if it is not (either no current path or a high impedance current path) the other logic state is represented. The bit is read at an output by either measuring the current flowing into the selected row line, column line or both (or into the entire array or a portion of the array) or by measuring the voltage on the selected row line, column line, or both. In the case of the current measurement, a larger current reading would indicate the presence of a current path at the addressed location. In the case of the voltage measurement, a convergence of the voltages applied to the selected row and selected column would indicate the presence of a current path at the addressed location. Writing is accomplished in a similar fashion except for a larger applied current or voltage that is sufficient to change the state of the targeted storage location.

It must be noted that the selected row will typically have many diodes connected whose addressing is not intended and these diodes will often experience a slight forward bias and source a slight forward current to the non-selected columns. Likewise, the selected column will typically have many diodes connected whose addressing is not intended and these diodes will often experience a slight forward bias and sink a slight forward current from the non-selected rows. To prevent these unintended diodes from becoming forward biased and wasting current the unselected orthogonal lines should be biased to approximately the same voltage as the selected line; this will put zero potential across the unintended diodes and, correspondingly, zero undesired current. A complication to this approach is that nearly all of the diodes at unselected storage locations will experience a reverse bias resulting in power consumption in the form of reverse leakage currents. To minimize this, the diodes should be made with crystalline material of the substrate or grown epitaxially from the substrate; in either case, the conductive lines below the diodes (in the substrate) will have to comprise the crystalline structure of the substrate.

A drawback to such diode arrays if either the bit-lines or word-lines of the array are implemented as a conducting line made of doped semiconductor material is that those lines will present a current leakage problem. If the lines of doped semiconductor are N-type semiconductor resulting in the diodes being oriented such that their P-type anodes are connected to the metal lines above and their N-type cathodes are connected to (or part of) the N-type semiconductor lines, below, to select one line out of the plurality, that line would be at a low potential whereas all of the remaining lines will have to be at a high potential. The drawback is that all of these remaining, unselected lines being at a high potential will create a plurality of reverse biased junctions to the p-type substrate, resulting in significant reverse leakage currents. This problem is not solved by reversing the direction of the diodes because to do this, all of the voltages and doping types would have to be reversed as well and the problem will represent itself in P-type lines being reverse biased to an n-type substrate.

What is needed is a diode array memory that keeps power consumption low by minimizing leakage currents, particularly those leakage currents resulting from applying a reverse bias across the unselected diodes in the memory array as well as from reverse biasing conductive lines formed of doped semiconductor in the substrate.

### SUMMARY

The present invention is a means for laying out and a method for manufacturing memory arrays to minimize leakage currents. The present invention will be useful for information storage technologies that utilize a non-linear conducting element (such as a diode) in the memory cell, as well as for any array of non-linear conducting elements (such as an array of diodes).

Embodiments of the present invention may include conductive strapping features that help to compensate for the series resistance of bit lines and/or word lines in order to provide greater current at a given memory cell while requiring lower supply voltages.

In an aspect, embodiments of the invention may include peripheral and/or support logic. This logic may comprise transistors.

In another aspect, embodiments of the invention may include self aligned features. In another aspect, embodiments of the invention may include implanting or other doping techniques, as well as doped deposition of semiconducting materials including epitaxial deposition of semiconducting materials, to form the various layers in the device.

The memory array built comprising the present invention may be programmed with data including or consisting essentially of music, video, computer software, a computer application, reference data, text, and/or a diagram. The memory array may be disposed within a removable memory storage device. The memory array may include or consist essentially of a plurality of storage cells. At least one of the storage cells may include or consist essentially of a phase-change material. The data will typically include error correcting bits, but might not in some cases.

Embodiments of the invention may be implemented with silicon based materials, however, other semiconducting materials are considered as well including III-V semiconductors, organic semiconductors, carbon nanotubes, and any other technology where a plurality of array lines utilize reverse biasing to isolate them from the surface on which they are fabricated. Embodiments of the invention may be implemented in conjunction with various information storage materials and techniques including resistive change materials, phase-change materials, magnetic materials (for MRAM), One Time Programmable (OTP) materials such as a fuse or anti-fuse material, charged oxide materials, trapped charge devices, and many more.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the invention. In the following description, various embodiments of the present invention are described with reference to the following drawing, in which:

FIG. 1 is an exemplary drawing of diodes constructed upon a conductive line in accordance with the prior art.

FIG. 2 is an exemplary drawing of an alternate implementation of diodes constructed upon a conductive line in accordance with the prior art.

FIG. 3 is an exemplary drawing of diodes constructed upon a layered conductive line in accordance with an embodiment of the invention.

### DETAILED DESCRIPTION

A low leakage diode array (or array of non-linear conductors that conduct current more easily in one direction than the other) can be fabricated using standard techniques and equipment. To do so, either the word-lines or the bit-lines may be fabricated as doped conductors in the substrate. This is often necessary because to minimize the reverse leakage of the unselected diodes in the array, the array diodes must be of high quality (i.e., they must be made of crystalline silicon as opposed to polysilicon, amorphous silicon, hydrogenated amorphous silicon, or other thin-film or deposited silicons). To construct the array diodes with crystalline silicon, this silicon must be formed from the crystalline silicon of the substrate (through patterning and etching) or it must be formed with an epitaxial process using the crystal lattice of the substrate as an initial framework for the epitaxial growth. In either case, the conductive line directly below those diodes must consist of crystalline silicon (i.e., be formed in the crystalline substrate as doped, crystalline semiconductor).

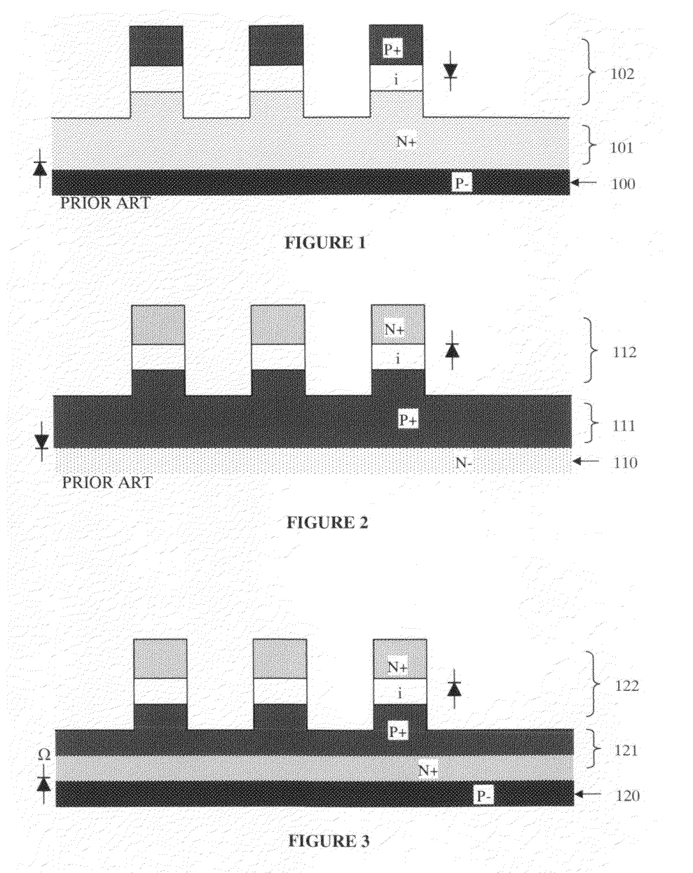

Referring to FIG. 1, a memory cell's diode 102 (of which three memory cells are depicted) on top of a conductor 101 made of N-type semiconductor on a P-type substrate 100 as taught by the prior art is depicted. Conductor 101 is typically surrounded by dielectric isolation and contacts the substrate only on its bottom surface. To form the diode 102 utilizing crystalline silicon, the diode 102 must sit directly upon crystalline silicon conductor 101. This is because diode 102 would have to have been etched or otherwise formed from the crystalline silicon substrate 100 (with an intervening layer of doped material for the conductor 101) or grown epitaxially from a crystalline seed surface (that surface being the upper surface of conductor 101 which would also have to be crystalline). As shown by the schematic symbol for a diode next to the memory cell, the memory cell diode points downward towards the conductor and the substrate meaning that the conductor must be brought to the low voltage in the circuit to select the conductor and access (forward bias) the memory cell diode and the P-type substrate 100 would have to biased to that same voltage or lower to prevent forward biased current flow from the conductor 101 into the substrate 100 as depicted by the diode symbol on the left side of the figure symbolizing the junction between the conductor 101 and the substrate 100; any unselected conductors 101, to be biased to an unselected voltage state that would prevent the selection of a memory cell diode connected thereto (i.e., ensure an unselected memory cell diode will not become forward biased), would have to be at a higher voltage than the selected conductor 101 resulting a reverse bias (and its associated leakage currents) between those conductors and the substrate.

Referring to FIG. 2, a diode 112 on top of a conductor 111 made of P-type semiconductor on an N-type substrate 110 as taught in the prior art is depicted. This variation from the prior art shows that the unselected conductor to substrate reverse bias leakage current is not eliminated if the polarity of the diode 112 is reversed because this reversal also requires the dopant of the conductor 111 and of the substrate 110 to be reversed. The difference is only that the reverse leakage current flows in the opposite direction (as depicted by the diode symbol on the left symbolizing the junction between the conductor 111 and the substrate 110).

Referring to FIG. 3, a diode 122 on top of a conductor 121 on a P-type substrate 120 as taught in the present invention is depicted. As is depicted in FIG. 1, the substrate 120 is made of P-type semiconductor but the diode is pointing in the direction as depicted in FIG. 2. This reversal of the direction of the diode while keeping the substrate junction direction is made possible by a dual-layer conductor 121. The diode could be formed in one of several ways that are well known to those skilled in the art including epitaxial growing of silicon (or other semiconductor material), patterning and etching. In FIG. 3, a diode 122 is formed by etching parallel trenches in a semiconductor substrate 120 in front and in back of conductor 121 and these trenches are then filled with dielectric such as silicon oxide or silicon nitride and then planarized as by CMP. This substrate will comprise layers of semiconducting material with a particular doping profile, the profile comprising layers for forming a conductive line (a bit-line or a word-line) 121 on top of which are layers for forming a diode 122. The diode layers comprise N-type semiconductor above and P-type semiconductor below and may, as taught in the prior art, also comprise an intervening layer of lightly doped or intrinsic semiconductor in between. The P-type semiconductor below may be comprised (in whole or in part) by the top layer of the conductive line's layers. The conductive line 121 layers will comprise P-type semiconductor above and N-type semiconductor below. The N-type semiconductor in the lower portion of the conductive lines will form a P-N junction with the substrate 120 (which must therefore be P-type) and this junction will experience either reverse bias or zero bias during normal operation of the array. The substrate will typically be biased with either a zero or negative voltage, but may be positively biased as long as it is less positively biased than any of the conductive lines formed therein (to prevent a forward biasing of the junction between the conductive line and the substrate that would waste current). The conductive line 121 will typically be surrounded by shallow trench isolation (STI) as described above and as is well known to those skilled in the art, and this STI will extend below the lower layer of the conductive lines (i.e., deeper than the N-type semiconductor in the lower portion of the conductive lines so as to separate adjacent conductive lines). The memory cell diodes 122 will typically be formed by patterning the diodes at their desired locations and etching the diodes into separate diode devices without etching so deep as to sever the conductive lines that must connect the diode bottoms together (i.e., etching down between the diodes without etching beyond the diode bottoms to the point of cutting through the conductive lines there below). The P-type and N-type layers of the conductor 121 can be doped to form an ohmic junction between the two layers (symbolized by the ohm symbol on the left), or they may be contacted by metal contacts (not shown) with these metal contacts then wired together (with appropriate ohmic contacting steps as are well known to those skilled in the art).

Embodiments of the present invention will typically, though not necessarily, include doped semiconductor layers in the conductor that are doped to higher dopant concentrations than the doping of the substrate.

Embodiments of the present invention will typically, though not necessarily, be built as integrated circuits by means of photolithography. The storage elements may include a fuseable material, an antifuseable material, a phase-change material (for PRAM) such as a chalcogenide alloy material (including a chalcogenide in which the programmed resistivity may be one of two resistance values and, in the case of more than one bit per cell storage cells, in which the programmed resistivity may be one of three or more resistance values), a resistive change material (for RRAM), a ferroelectric material (for FRAM), a magnetic or magnetoresistive material (for MRAM), magnetic tunnel junction or spin-transfer torque element (for MTJ-RAM or STT-RAM), a dual layer oxide memory element comprising a junction and an insulating metal oxide and a conductive metal oxide (see U.S. Pat. No. 6,753,561 by Rinerson), or a trapped charge device (see U.S. Pat. No. 7,362,609 by Harrison, et al). The phase-change material, such as a Chalcogenide material, may be programmed or erased. Orientation of the array may be rotated, i.e., the “rows” may be “columns,” or vice versa. The polarity of the voltages and direction of the steering elements in the storage bits may be reversed while still keeping within what is envisioned by embodiments of the present invention. The present invention may be applied to other memory technologies as well including static RAM, Flash memory, EEPROM, DRAM, and others not mentioned, including memory technologies yet to be commercialized or invented.

Memory devices incorporating embodiments of the present invention may be applied to memory devices and systems for storing digital text, digital books, digital music (such as MP3 players and cellular telephones), digital audio, digital photographs (wherein one or more digital still images may be stored including sequences of digital images), digital video (such as personal entertainment devices), digital cartography (wherein one or more digital maps can be stored, such as GPS devices), and any other digital or digitized information as well as any combinations thereof. Devices incorporating embodiments of the present invention may be embedded or removable, and may be interchangeable among other devices that can access the data therein. Embodiments of the invention may be packaged in any variety of industry-standard form factor, including Compact Flash, Secure Digital, MultiMedia Cards, PCMCIA Cards, Memory Stick, any of a large variety of integrated circuit packages including Ball Grid Arrays, Dual In-Line Packages (DIPs), SOICs, PLCC, TQFPs and the like, as well as in proprietary form factors and custom designed packages. These packages may contain just the memory chip, multiple memory chips, one or more memory chips along with other logic devices or other storage devices such as PLDs, PLAs, micro-controllers, microprocessors, controller chips or chip-sets or other custom or standard circuitry.

The terms and expressions employed herein are used as terms and expressions of description and not of limitation, and there is no intention, in the use of such terms and expressions, of excluding any equivalents of the features shown and described or portions thereof. In addition, having described certain embodiments of the invention, it will be apparent to those of ordinary skill in the art that other embodiments incorporating the concepts disclosed herein may be used without departing from the spirit and scope of the invention. Accordingly, the described embodiments are to be considered in all respects as only illustrative and not restrictive.

What is claimed is:

1. A memory device comprising a plurality of memory cells each comprising a non-linear conductor connected to a conductor such that, during normal operation, an unselected conductor has a zero bias to the substrate and a selected conductor has a reverse bias to the substrate.

2. The conductor of claim 1 comprising a first layer of doped semiconductor material.

3. The conductor of claim 2 comprising a second layer of semiconductor material doped to a polarity opposite that of the first layer.

4. The conductor of claim 3 whereby said first layer is doped to a polarity opposite that of the substrate.

5. The semiconductor materials of claim 4 whereby the doping concentrations need not be the same.

6. The semiconductor materials of claim 4 whereby the doping concentration of at least one layer in the conductor is greater than the doping concentration of the substrate.

7. The conductor of claim 4 whereby the first and second layer are connected by an ohmic connection.

8. The conductor of claim 7 whereby the boundary between the first and second layer is an ohmic connection.

9. The conductor of claim 4 whereby the first and second layer are ohmically connected by a metal connection.

10. A memory structure comprising a memory cell and a conductor, the memory cell further comprising a non-linear device and the conductor comprising doped semiconductor.

11. The memory cell of claim 10 comprising at least one from the list of a fuseable material, an antifuseable material, a phase-change material, a chalcogenide material, a resistive change material, a ferroelectric material, a magnetic material, a magnetoresistive material, a magnetic tunnel junction, a spin-transfer torque element, a dual layer oxide, a junction, an insulating metal oxide, a conductive metal oxide, or a trapped charge device.

12. The memory structure of claim 10 whereby the memory structure is contained in a package that is removable and interchangeable among two or more devices.

13. The memory cell of claim 10 whereby the memory cell stores information comprising at least one from the list of text, books, music, audio, photographs, still images, sequences of images, video, or cartography.

14. A method of forming a memory device comprising forming layers of material that can be etched to produce a plurality memory cells each comprising a non-linear conductor connected to a conductor such that, during normal operation, an unselected conductor has a zero bias to the substrate.

15. The memory device of claim 14 whereby the non-linear conductor comprises a P-type layer and an N-type layer.

16. The non-linear conductor of claim 15 further comprising a layer of intrinsic or lightly doped semiconductor material between the P-type and N-type layers.

17. The memory cell of claim 14 whereby the area occupied by the memory cell is 4F².

18. A memory device that is removable and interchangeable comprising a plurality of conductors such that, during normal operation, an unselected conductor has a zero bias to its substrate and a selected conductor has a reverse bias to its substrate.
